(19) United States
(12) Patent Application Publication
(10) Pub. No.: US 2009/0115018 A1
(43) Pub. Date: May 7, 2009

(54) Transient voltage suppressor manufactured in silicon on oxide (SOI) layer

(75) Inventor: Shekar Mallikarjunaswamy, San Jose, CA (US)

Correspondence Address: Bo-In Lin, 13445 Mandoli Drive, Los Altos Hills, CA, 94022, US

(73) Assignee: Alpha & Omega Semiconductor, LTD

(21) Appl. No.: 11/982,557

(22) Filed: Nov. 1, 2007

(51) Int. Cl. H01L 27/06; H01L 21/8222

(52) U.S. Cl. 257/517; 438/380; 257/E27.023; 257/E21.608

(57) ABSTRACT

A transient voltage-suppressing (TVS) device supported on a semiconductor substrate is applied to protect an electronic device from a transient voltage. The TVS device includes a clamp diode functions with a high-side and a low side diodes for clamping a transient voltage disposed on a top layer of the semiconductor substrate insulated by a insulation layer constituting a TVS on silicon-on-insulator (SOI) device. In an exemplary embodiment, the insulator layer further includes a thick body oxide (BOX) layer having a thickness in the range of 250 Angstroms to 1 micrometer to sustain an application with a breakdown voltage higher than 25 volts. In another exemplary embodiment, the clamp diode further surrounded by a P-well and the P-well is formed on top of a P−/P+ substrate layer disposed above the insulator layer.

### BACKGROUND OF THE INVENTION

1. Field of the Invention

The invention relates generally to a circuit configuration and method of manufacturing a transient voltage suppressor (TVS). More particularly, this invention relates to an improved circuit configuration and method of manufacturing TVS in a silicon-on-insulator (SOI) layer for providing TVS protection with low capacitance.

2. Description of the Relevant Art

The conventional technologies for designing and manufacturing transient voltage suppressor (TVS) are still confronted with certain technical difficulty. Particularly, when the TVS is formed with multiple PN junctions diodes in a semiconductor substrate by applying standard CMOS processing steps, there are inherent PNP and NPN parasitic transistors. In an ESD event or the occurrence of a transient voltage, with a larger voltage applied to this TVS array, the parasitic NPN or PNP transistors are turned on and latched up. The latch-up may cause sudden and strong voltage snapback. The sudden and large snapback may cause the undesired effects of system instability or even damages. Additionally, the latch-up of the parasitic NPN or PNP transistors in the TVS array may further lead to other unexpected or undesirable voltage-current transient conditions. The technical difficulties caused by the parasitic capacitance and parasitic PNP or NPN latch-up in a device implemented with the TVS protection cannot be easily resolved.

Generally, the transient voltage suppressors (TVS) are commonly applied to protecting integrated circuits from damages due to the inadvertent occurrence of an over-voltage imposed onto the integrated circuit. An integrated circuit is designed to operate over a normal range of voltages. However, in situations such as electrostatic discharge (ESD), electrical fast transients and lightning, an unexpected and uncontrollable high voltage may accidentally strike onto the circuit. The TVS devices are required to serve the protection functions to circumvent the damages that are likely to occur to the integrated circuits when such over-voltage conditions occur. As increasing numbers of devices are implemented with the integrated circuits that are vulnerable to over-voltage damages, demands for TVS protection are also increased. Exemplary applications of TVS can be found in the USB power and data line protection, digital video interface, high-speed Ethernet, notebook computers, monitors and flat panel displays.

FIGS. 1A and 1B show a circuit diagram and a current-voltage diagram respectively of a TVS device. An ideal TVS totally blocks the current (i.e., zero current) when the input voltage Vin is less than the breakdown voltage Vb, for minimizing the leakage current. And, ideally, the TVS has close to zero resistance under the circumstance when the input voltage Vin is greater than the breakdown voltage Vb such that the transient voltage can be effectively clamped. A TVS can be implemented with the PN junction device that has a breakdown voltage which allows current conduction when a transient input voltage exceeds the breakdown voltage to achieve the transient voltage protection. However, the PN junction type of TVS has no minority carriers and has a poor clamping performance due to its high resistance as that shown in FIG. 1B. There are alternate TVS implementations with bipolar NPN/PNP with an avalanche-triggered turning-on of the bipolar transistor. The base is flooded with minority carriers and the bipolar TVS can achieve better clamping voltage as the avalanche current is amplified with the bipolar gain.

With the advancement of electronic technologies, there are increasingly more devices and applications that require TVS diode array for ESD protection, particularly for protecting high bandwidth data buses. Referring to FIG. 2A for a circuit diagram of a four channel TVS and FIG. 2B for side cross sectional views of device implementation of the TVS array showing only the core of the array device. The TVS array as shown in FIGS. 2A and 2B includes a plurality of high-side and low-side steering diodes connected in series wherein the high-side steering diodes are connected to Vcc and the low-side steering diodes connected to ground potential. Furthermore, these high-side and low-side steering diodes are connected in parallel to a main Zener diode wherein the steering diodes are much smaller and have lower junction capacitance. Additionally, as shown in FIG. 2C, such implementation further generates another problem of latch-up due to the silicon-controlled rectifier (SCR) action induced by parasitic PNP and NPN transistors. The main Zener diode breakdown triggers the NPN on, which further turns on the SCR, resulting in latch-up. In high temperature, the high leakage current through the NP junction of the parasitic NPN may also turn on the SCR leading to latch-up even though the NPN is not turned on. To suppress latch-up due to the SCR action induced by parasitic PNP and NPN transistors, the actual device implementation on a semiconductor substrate requires a lateral extension on the substrate of a distance that may be up to 100 micrometers or more as shown in FIG. 2B and the suppression usually is not effective enough.

Therefore, a need still exists in the fields of circuit design and device manufactures for providing a new and improved circuit configuration and manufacturing method to resolve the above-discussed difficulties. Specifically, a need still exists to provide new and improved TVS circuits that can effectively and conveniently reduce the capacitance and also prevent the parasitic PNP/NPN transistor latch-up.

### SUMMARY OF THE PRESENT INVENTION

It is therefore an aspect of the present invention to provide a new and improved device structure to implement a TVS in the SOI structure to reduce the parasitic capacitance and to prevent the latch-up of the parasitic PNP-NPN transistors such that the above-discussed difficulties and limitations encountered by the conventional TVS array can be overcome.

Another aspect of the present invention is to form the TVS protective circuit in the SOI layer. The lateral distance between adjacent diodes can be reduced without the concerns of parasitic capacitance and inadvertent latch-up.

Briefly in a preferred embodiment this invention discloses a transient voltage-suppressing (TVS) device supported on a semiconductor substrate. The TVS device includes a clamp diode functioning with a high-side and a low side diodes for clamping a transient voltage disposed on a top layer of the semiconductor substrate insulated by a insulation layer constituting a TVS on silicon-on-insulator (SOI) device. In an exemplary embodiment, the insulator layer further includes a thick body oxide (BOX) layer. In another specific exemplary embodiment, the insulator layer further includes a thick body oxide (BOX) layer having a thickness in the range of 250 Angstroms to 1 micrometer to sustain an application with a breakdown voltage higher than 25 volts. In another exemplary embodiment, the clamp diode further surrounded by a P-well and the P-well is formed on top of a P−/P+ substrate layer disposed above the insulator layer.

The present invention further discloses a method for manufacturing an electronic device with an integrated transient voltage-suppressing (TVS) device. The method includes a step of manufacturing the TVS array in a semiconductor substrate by forming a silicon layer above an insulator as a silicon on insulator (SOI) layer and forming a clamping diode to function with high-side and low-side diodes for clamping a transient voltage of said electronic device in the SOI layer. In an exemplary embodiment, the process of forming the insulation layer further includes a step of forming a thick body oxide layer in the semiconductor substrate. In a specific embodiment, the BOX layer is formed by forming a thick oxide layer on top surface of P− wafers then bonding and fusing the oxide layers of two wafers face to face together then lapping the substrate to a desired thickness. In another specific embodiment, the method further includes a step of deep dopant implanting the semiconductor substrate to convert a P− substrate layer above the BOX layer into a P+ layer.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

FIG. 1A is a circuit diagram to show a conventional TVS device and FIG. 1B is an I-V diagram, i.e., a current versus voltage diagram, for illustrating the reverse characteristics of the TVS device.

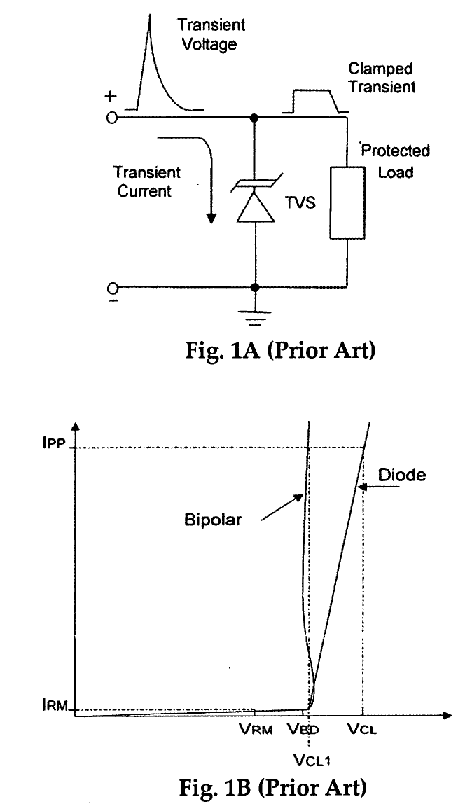

FIG. 2A shows a circuit diagram of a TVS array comprising a plurality of high side and low side diodes connected to a plurality of input/output (I/O) pads with a main Zener diode connected in parallel to the high side and low side diodes.

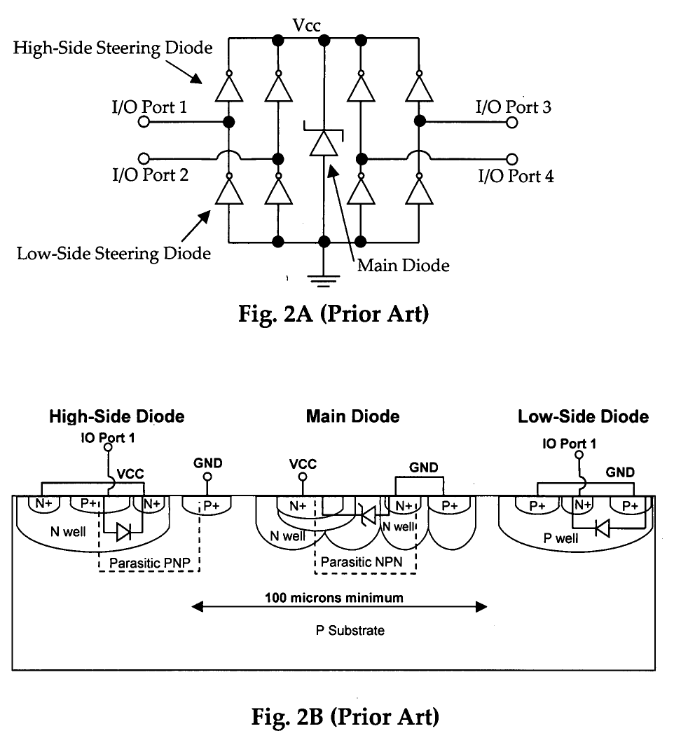

FIG. 2B is a side cross sectional view for illustrating device implementation of the TVS array of FIG. 2A according to a conventional device configuration.

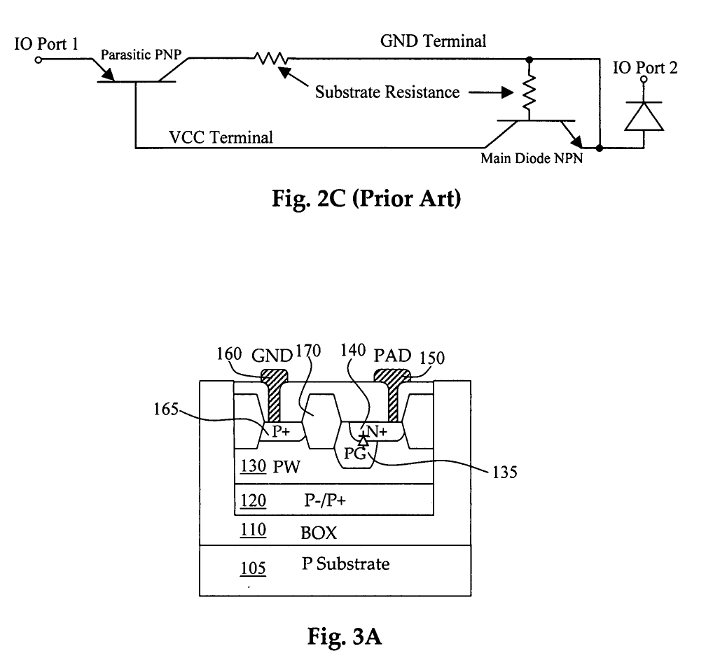

FIG. 2C shows the equivalent circuit diagram for illustrating the potential latch-up of device as implemented in FIG. 2B

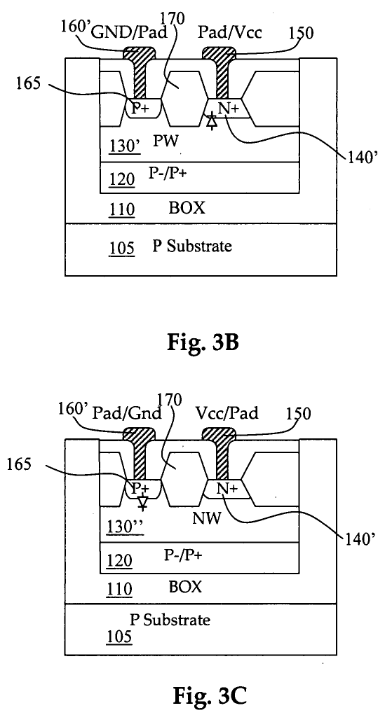

FIG. 3A to 3C are side cross sectional views of a clamp diode, a low/high side diode and a low/high side diode respectively of a TVS built in a SOI layer with deep oxide trench and thick silicon on a semiconductor substrate of this invention.

FIGS. 3D and 3E are side cross sectional views of a TVS of FIG. 3A implemented with a lateral NPN and lateral NW NPN configuration respectively of this invention.

FIG. 4A to 4C are side cross sectional views of a clamp diode, a low/high side diode and a low/high side diode respectively of a TVS built in a SOI layer with a thin silicon partially depleted semiconductor substrate of this invention.

FIGS. 4D and 4E are side cross sectional views of a TVS of FIG. 4A implemented with a lateral NPN and lateral NW NPN configuration respectively of this invention.

FIGS. 5A to 5C are side cross sectional views of a clamp diode, a low/high side diode and a low/high side diode respectively of a TVS built in a SOI layer with a fully depleted silicon semiconductor substrate of this invention.

FIGS. 5D and 5E are side cross sectional views of a TVS of FIGS. 5A to 4C implemented with a lateral NPN and lateral NW NPN configuration respectively of this invention.

### DETAILED DESCRIPTION OF THE METHOD

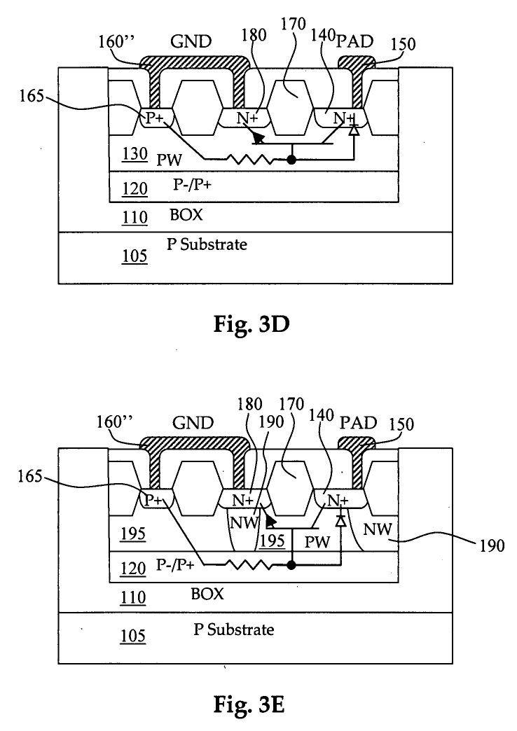

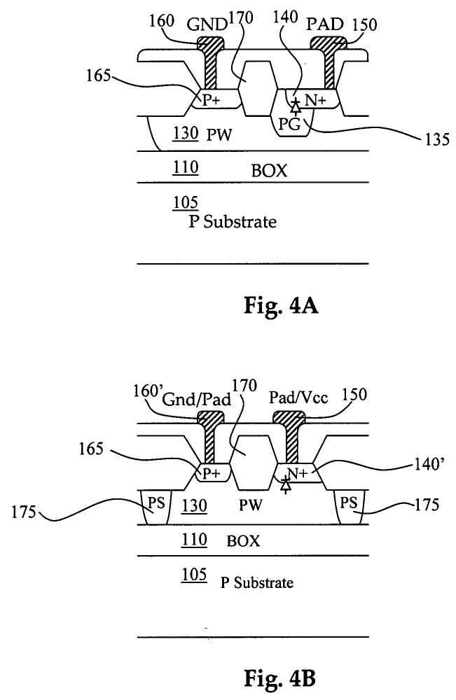

FIGS. 3A to 3C are a cross sectional views showing the clamp diode and the high/low side diode of the TVS formed on a silicon on insulator (SOI) of this invention. A thick body oxide (BOX) layer 110 is deposited on a P type substrate 105. The BOX layer 110 has a thickness in the range of 250 A to 1 um to sustain an application with a breakdown voltage higher than 25 volts. Formation of BOX may be carried out by forming a thick oxide layer on top surface of P− wafers then bonding and fusing the oxide layers of two wafers face to face together then lapping the substrate to a desired thickness, which is a well known process. Optional deep dopant implant may be applied to convert a P− substrate layer above the BOX layer into a P+ layer. In the embodiment as shown in FIG. 3A, the clamp diode is formed in a P well (PW) 130 on top of an optional P−/P+ substrate layer 120. A grade doping profile of P doped region 135 provides trigger voltage adjustment for a clamp diode formed by the junction between N+ region 140 and P graded region 135. The PN junction is displaced away from diode cathode metal pad 150 to avoid melt down during high current breakdown. A distance between P grade region 135 and P+ anode contact region 165 provides distributed resistance required for triggering a bipolar connected in the circuit. A local oxidized silicon (LOCOS) layer 170 separates the P graded dopant region 140 from the P+ anode contact region 165 that is connected to the anode electrode 160. Alternatively, instead of the LOCOS layer 170, a Shallow Trench Isolation (STI) that is not specifically shown may be used.

The low/high side diodes can be formed in a different area of die during the same process on the same substrate 105 with a BOX layer 110 including an optional P−/P+ substrate layer 120. FIG. 3B shows the low/high side diode formed in P well 130′ formed simultaneously with the PW 130. The diode between the N+ region 140′ and the P well 130′ is formed simultaneously with the N+ region 140. FIG. 3C shows the high/low side of diodes wherein both high/low side diode can be formed in N well, e.g., NW region 130″. The high side and low side diodes are formed by the anode contact region 165′ and the NW 130″. Accordingly, the clamp diode can also be formed in the N-well NW (not specifically shown).

In order to improve the voltage clamping, a bipolar NPN transistor is implemented in an exemplary embodiment between the N+ cathode dopant region 140, the PW 130 and the N+ dopant region 165 to replace diode as main clamping element shown in FIG. 3D. FIG. 3D shows a lateral NPN transistor disposed in a P well. Specifically, the N+ region 140, P well 130 and N+ region 180 forms a NPN transistor. In the meantime, the N+ region 140 and P well 130 further forms the triggering diode whereas when a transient voltage arrives the junction between N+ 140 and P well 130 will breakdown first and current will flow through P well to P+ region 165 connected to ground through the electrode 160. When the current grows high enough the voltage drop due by distributive resistance in P well 130 will turn on the bipolar NPN transistor thus providing an improved clamping function. FIG. 3E shows an alternative embodiment where the lateral NPN structure further includes N well 190 and N well 195. The N well 190 ensures PN junction is displaced away from diode cathode metal pad 150 to avoid melt down during high current breakdown. The N well 190 enlarges the base region by extending the emitter to deeper depth therefore providing deeper carrier injection for increases the high current handling capability. The N well 190 further increases base resistance for the benefit of easier turn on the bipolar NPN at an even lower current.

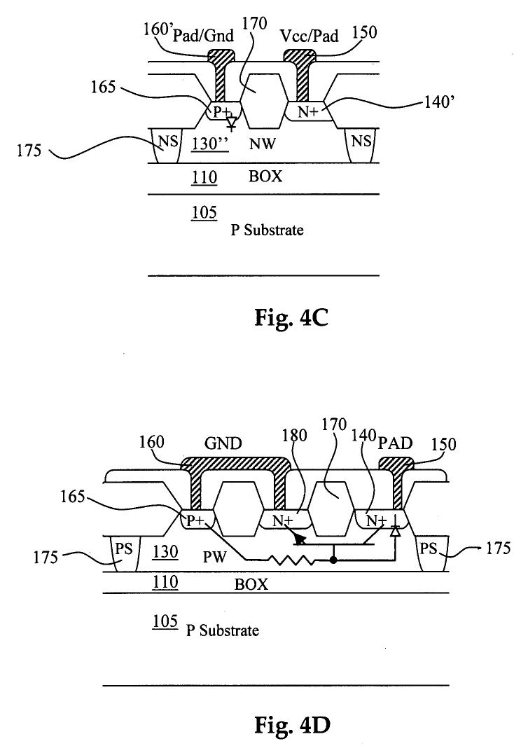

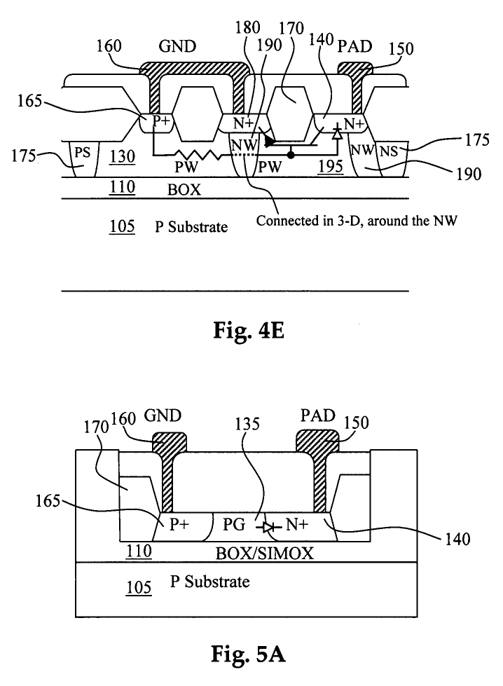

Referring to FIGS. 4A to 4E for the embodiments of TVS built on thin silicon layer (about 1 um) where the thin layer of silicon is partially depleted. FIG. 4A is an alternative embodiment of FIG. 3A where the bottom of P well 130 extends to the BOX layer 110, eliminating the P−/P+ layer 120. FIGS. 4B to 4E are corresponding to FIGS. 3B to 3E. In addition to the elimination of P−/P+ layer 120 due to the depletion of thin silicon layer, the devices of FIGS. 4B to 4E also use sinker regions 175 instead of oxide trench as shown in FIGS. 3B-3E to isolate the device from other regions. The heavy dope sinker regions 175 provide heavy dope base regions of parasitic bipolar transistors therefore suppress the gain of parasitic bipolar to avoid snap back that would cause latch up. The use of sinker also provides the flexibility to adjust the distance between the devices.

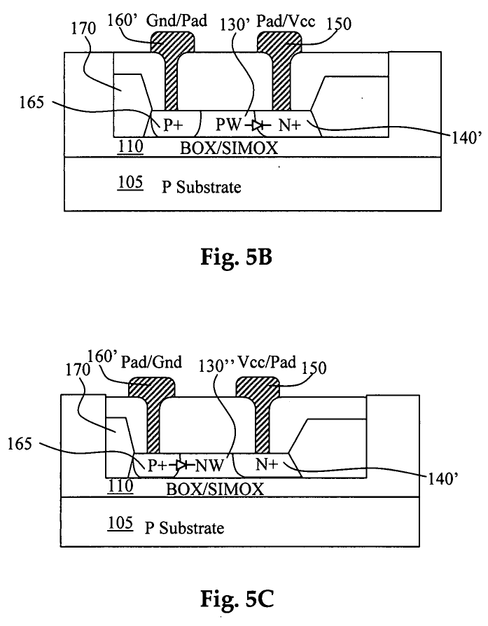

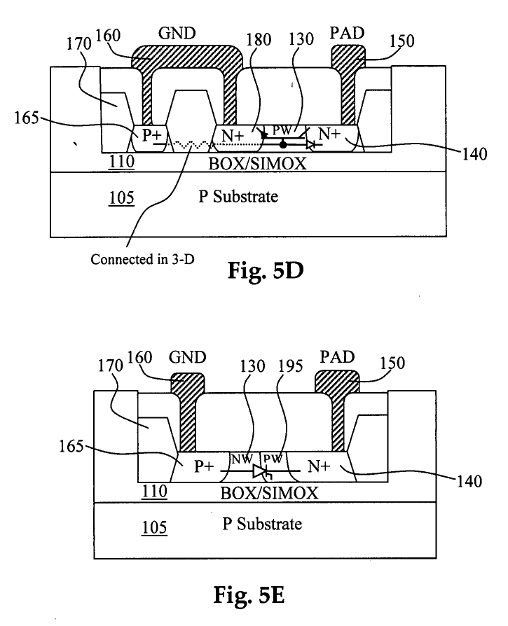

Referring to FIGS. 5A to 5E for the embodiments of TVS built on fully depleted silicon layer manufactured by use of a well-known approach in CMOS technology. FIGS. 5A to 5E are corresponding to the device of FIGS. 3A to 3E. The difference in FIGS. 5A to 5E from the embodiment shown in FIG. 3A to E is to manufacture the device on a very thin silicon layer. In order to form the TVS device in a thin silicon layer, the TVS device is now manufactured with the P−/P+ layer 120 and P well layer 130 shown in FIGS. 3A-3E eliminated. As the Silicon layer is thin it is now possible to implant Oxygen into the substrate to form a thin layer of Silicon Implant Oxide (SIMOX) to replace the thick BOX layer to reduce manufacturing cost. As shown in FIGS. 5D and 5E, the cross sections show a lateral bipolar transistor and a lateral SCR device respectively. The triggering diode paths are connected in third dimension (not shown). It is understood that the complementary devices can be made based on the above structure by simply switching the polarity of dopant type.

Although the present invention has been described in terms of the presently preferred embodiment, it is to be understood that such disclosure is not to be interpreted as limiting. Various alterations and modifications will no doubt become apparent to those skilled in the art after reading the above disclosure. Accordingly, it is intended that the appended claims be interpreted as covering all alterations and modifications as fall within the true spirit and scope of the invention.

1. A transient voltage suppressing (TVS) device supported on a semiconductor substrate comprising:
a clamp element functioning with a high-side and a low side diodes for clamping a transient voltage disposed on a top layer of said semiconductor substrate insulated by a insulation layer constituting a TVS on silicon-on-insulator (SOI) device.

2. The TVS device of claim 1 wherein:
said insulator layer further comprising a thick body oxide (BOX) layer.

3. The TVS device of claim 1 wherein:
said insulator layer further comprising a thick body oxide (BOX) layer having a thickness in the range of 250 Angstroms to 1 micrometer to sustain an application with a breakdown voltage higher than 25 volts.

4. The TVS device of claim 1 wherein:
said clamp element further surrounded by a P-well.

5. The TVS device of claim 1 wherein:
said clamp element further surrounded by a P-well on top of a P−/P+ substrate layer disposed above said insulator layer.

6. The TVS device of claim 1 wherein:
said clamp element further comprising a Zener diode.

7. The TVS device of claim 6 wherein:
said Zener diode further comprising a graded doping region.

8. The TVS device of claim 1 wherein:
said clamp element further comprising a bipolar transistor triggered by a diode.

9. The TVS device of claim 8 wherein:
said bipolar transistor further comprising extending emitter region for enlarging the base region by providing deeper carrier injection for increases the high current handling capability.

10. The TVS device of claim 1 wherein:
said insulator layer further comprising a thin layer of Silicon Implant Oxide (SIMOX).

11. The TVS device of claim 1 further comprising:
heavily doped sinkers to insulate the clamp element from other functional devices.

12. The TVS device of claim 1 further comprising:
dielectric material filling trenches to insulate the clamp element from other functional devices.

13. A method for manufacturing an electronic device with an integrated transient voltage-suppressing (TVS) device comprising:
manufacturing the TVS device in a semiconductor substrate by forming a silicon layer above an insulator as a silicon on insulator (SOI) layer and forming a clamping diode to function with high-side and low-side diodes for clamping a transient voltage of said electronic device in the SOI layer.

14. The method for claim 13 wherein:
the process of forming the insulation layer further includes a step of forming a thick body oxide layer in the semiconductor substrate.

15. The method for claim 13 wherein: the process of forming the insulation layer further includes a step of forming a thick body oxide layer in the semiconductor substrate by forming a thick oxide layer on top surface of P-wafers then bonding and fusing the oxide layers of two wafers face to face together then lapping the substrate to a desired thickness.

16. The method for claim 13 further comprising:
deep dopant implanting the semiconductor substrate to convert a P−substrate layer above the BOX layer into a P+layer.
